(19) United States
(12) Patent Application Publication
(10) Pub. No.: US 2011/0147757 A1
(43) Pub. Date: Jun. 23, 2011

(54) ARRAY SUBSTRATE OF DISPLAY DEVICE

(75) Inventors: Ki-Hoon KIM, Yongin-city (KR); Jin-Suk PARK, Yongin-city (KR); Ji-Yong PARK, Yongin-city (KR); Kyung-Min PARK, Yongin-city (KR); Kyung-Hyun CHOI, Yongin-city (KR); Gyung-Soon PARK, Yongin-city (KR); Dae-Won LEE, Yongin-city (KR)

(73) Assignee: Samsung Mobile Display Co., Ltd., Yongin-City (KR)

(21) Appl. No.: 12/968,456

(22) Filed: Dec. 15, 2010

(30) Foreign Application Priority Data
Dec. 17, 2009 (KR) 10-2009-0126070

(51) Int. Cl. H01L 29/786; H01L 33/00; H01L 33/08; H01L 29/04

(52) U.S. Cl. 257/71; 257/49; 438/34; 257/72; 257/E33.064; 257/E29.003; 257/E29.273; 257/E33.001

(57) ABSTRACT

An array substrate of a display device, the array substrate: a substrate having a first region and a second region spaced apart from the first region; a blocking layer located on the substrate; a first electrode located on the blocking layer in the second region; an insulating film located on the blocking layer to cover the first electrode; a second electrode located on the insulating film to overlap the first electrode; and a third electrode overlapping the first electrode between the substrate and the blocking layer. Accordingly, it is possible to reduce an area that is occupied by a storage capacitor in a pixel region and to achieve high luminance by increasing the aperture ratio, by providing a structure and method of increasing a storage capacitance of the same area.

### CROSS-REFERENCE TO RELATED APPLICATION

This application claims the benefit of Korean Patent Application No. Korean Patent Application No. 10-2009-0126070, filed on Dec. 17, 2009, in the Korean Intellectual Property Office, the disclosure of which is incorporated herein by reference.

### BACKGROUND

1. Field

Non-limiting example embodiments of the present invention relate to a display device. In detail, non-limiting example embodiments of the present invention relate to an array substrate of a display device capable of implementing images, such as characters and pictures. The display device may include a liquid display device, an organic light emitting device, etc.

2. Description of the Related Art

The display device may include a liquid crystal display device. The liquid crystal display device may display pictures by adjusting light transmittance of a liquid crystal, using an electric field. Such liquid crystal display devices drive the liquid crystal by controlling the electric field between a pixel electrode and a common electrode located to face each other on a lower substrate. The lower substrate is an array substrate with a thin film transistor, and an upper substrate has a color filter. The liquid crystal display devices include an upper plate and a lower plate bonded to face each other, a spacer maintaining a cell gap between the lower substrate and the upper substrate, and liquid crystal located in the cell gap.

The thin film transistor includes a semiconductor layer providing a channel region, a source region, and a drain region, which are also known as an active layer, and a gate electrode formed over the channel region and electrically connected with the active layer by an insulating film. The semiconductor layer having the above configuration of the thin film transistor is typically formed using amorphous silicon or poly-silicon. When the semiconductor layer is formed using amorphous silicon, it is difficult to implement a driving circuit that operates at high speed on account of low electron mobility.

On the other hand, when the semiconductor layer is formed using poly-silicon, a threshold voltage becomes non-uniform due to a polycrystalline nature of the semiconductor layer, although electron mobility is high. When the semiconductor layer formed using LPTS (Low-temperature poly-silicon) has high electron mobility and direct current (DC) stability, and thus, the LTPS thin film transistor has been increasingly used in recent years.

Furthermore, the upper substrate of the liquid crystal display devices is composed of a color filter implementing colors, a black matrix preventing light leakage, a common electrode controlling the electric field, and an alignment film coated to arrange the liquid crystal. The lower substrate is composed of a plurality of signal wirings and the thin film transistor, a pixel electrode connected with the thin film transistor, and an alignment film coated to arrange the liquid crystal. The lower substrate has a storage capacitor to stably hold a pixel voltage charged in the pixel electrode until the next voltage signal is charged.

The storage capacitor is formed by overlapping a lower storage electrode and an upper storage electrode and disposing an insulating film therebetween. The storage capacitor requires a large capacity to achieve high resolution while keeping a pixel voltage signal stable. A way of increasing the overlap area of the upper storage electrode and the lower storage electrode is used to increase the capacity of the storage capacitor. However, the increased overlap area reduces the aperture ratio of the pixel corresponding to the area that the upper storage electrode and the lower storage electrode occupy.

### SUMMARY

Non-limiting example embodiments of the present invention provide an array substrate of a display device capable of easily achieving desired capacitance from a limited area.

According to non-limiting example embodiments of the present invention, there is provided an array substrate of a display device, the array substrate including: a substrate having a first region and a second region spaced apart from the first region; a blocking layer located on the substrate; a first electrode located on the blocking layer in the second region; an insulating film located on the blocking layer to cover the first electrode; a second electrode located on the insulating film to overlap the first electrode; and a third electrode overlapping the first electrode between the substrate and the blocking layer.

According to another non-limiting example embodiment of the present invention, there is provided an array substrate of a display device, the array substrate including: a substrate having a first region and a second region spaced apart from the first region; a blocking layer located on the substrate; a first electrode located on the blocking layer in the second region; an insulating film located on the blocking layer to cover the first electrode; a second electrode located on the insulating film to overlap the first electrode; an interlayer insulating film located on the second electrode; and a fourth electrode overlapping the second electrode on the interlayer insulating film.

According to another non-limiting example embodiment of the present invention, there is provided an array substrate of a display device, the array substrate including: a substrate having a first region and a second region spaced apart from the first region; a blocking layer located on the substrate; a first electrode located on the blocking layer in the second region; an insulating film located on the blocking layer to cover the first electrode; a second electrode located on the insulating film to overlap the first electrode; a third electrode overlapping the first electrode between the substrate and the blocking layer; an interlayer insulating film located on the second electrode; and a fourth electrode overlapping the second electrode on the interlayer insulating film.

According to another non-limiting example embodiment of the present invention, there is provided an array substrate of a display device, the array substrate including: a substrate having a first region and a second region spaced apart from the first region; a blocking layer located on the substrate; a first electrode located on the blocking layer in the second region; an insulating film located on the blocking layer to cover the first electrode; a second electrode located on the insulating film to overlap the first electrode; and a transistor located in the first region. The transistor includes a channel region, a source region connected with the channel region, and a drain region and a gate region, wherein the drain region and the gate region are spaced apart from the source region. The insulating film insulates the channel region, the source region, and the drain region and the gate region.

According to another non-limiting example embodiment of the present invention, there is provided an array substrate of a display device, the array substrate including: a substrate having a first region and a second region spaced apart from the first region; a blocking layer located on the substrate; a first electrode located on the blocking layer in the second region; an insulating film located on the blocking layer to cover the first electrode; a second electrode located on the insulating film to overlap the first electrode; a transistor located in the first region; and a light block layer overlapping the transistor between the substrate and the blocking layer.

According to another non-limiting example embodiment of the present invention, there is provided an array substrate of a display device, the array substrate including: a substrate having a first region and a second region spaced apart from the first region; a blocking layer located on the substrate; a transistor located in the first region, and includes a semiconductor layer, a gate electrode located in a region that overlaps the semiconductor layer, and an insulating film insulating the gate electrode from the semiconductor layer; a light block layer overlapping the transistor between the substrate and the blocking layer; a second electrode located on the insulating film in the second region and used as the upper electrode of a storage capacitor; and a third electrode overlapping the upper electrode of the storage capacitor and located under the blocking layer in the second region, and wherein the third electrode is used as the lower electrode of the storage capacitor.

According to non-limiting example embodiments of the present invention, in an array substrate of a display device using poly-silicon, it is possible to reduce the area that is occupied by a storage capacitor in a pixel region and achieve high luminance by increasing the aperture ratio, by providing a structure and method of increasing storage capacitance to the same area.

Additional aspects and/or advantages of the invention will be set forth in part in the description which follows and, in part, will be obvious from the description, or may be learned by practice of the invention.

### BRIEF DESCRIPTION OF THE DRAWINGS

These and/or other aspects and advantages of the invention will become apparent and more readily appreciated from the following description of the non-limiting example embodiments, taken in conjunction with the accompanying drawings of which:

FIG. 1 is a cross-sectional view showing an array substrate of a display device according to a non-limiting example embodiment of the present invention;

FIG. 2 is a cross-sectional view showing an array substrate of a display device according to a non-limiting example embodiment of the present invention;

FIG. 3 is a cross-sectional view showing an array substrate of a display device according to a non-limiting example embodiment of the present invention;

FIG. 4 is a cross-sectional view showing an array substrate of a display device according to a non-limiting example embodiment of the present invention;

FIG. 5 is a cross-sectional view showing an array substrate of a display device according to a non-limiting example embodiment of the present invention; and

FIG. 6 is a cross-sectional view showing an array substrate of a display device according to a non-limiting example embodiment of the present invention.

### DETAILED DESCRIPTION OF THE NON-LIMITING EXAMPLE EMBODIMENTS

Reference will now be made in detail to the present non-limiting example embodiments of the present invention, examples of which are illustrated in the accompanying drawings, wherein like reference numerals refer to the like elements throughout. The non-limiting example embodiments are described below in order to explain the present invention by referring to the figures.

As referred to herein, it is to be understood that when it is stated that one film, element or layer is “formed on” or “located on” a second layer or film, the first layer, element or film may be formed or located directly on the second layer, element or film or there may be intervening layers, elements or films between the first layer, element or film and the second layer, element or film. Furthermore, as used herein, the term “formed on” is used with the same meaning as “located on” or “located on” and is not meant to be limiting regarding any particular fabrication process. Additionally, some of the elements that are not essential to the complete understanding of the invention are omitted for clarity.

It will be understood that, although the terms first, second, third, etc., may be used herein to describe various elements, components, regions, layers and/or sections, these elements, components, regions, layers and/or sections should not be limited by these terms. These terms are only used to distinguish one element, component, region, layer or section from another element, component, region, layer or section. Thus, a first element, component, region, layer or section discussed below could be termed a second element, component, region, layer or section without departing from the teachings of the present invention.

The terminology used herein is for the purpose of describing particular non-limiting example embodiments only and is not intended to be limiting of the invention. As used herein, the singular forms “a,” “an” and “the” are intended to include the plural forms as well, unless the context clearly indicates otherwise. It will be further understood that the terms “comprises” and/or “comprising,” or “includes” and/or “including” when used in this specification, specify the presence of stated features, regions, integers, steps, operations, elements, and/or components, but do not preclude the presence or addition of one or more other features, regions, integers, steps, operations, elements, components, and/or groups thereof.

As referred to herein, relative terms, such as “lower” or “bottom” and “upper” or “top,” may be used herein to describe one element's relationship to other elements as illustrated in the Figures. It will be understood that relative terms are intended to encompass different orientations of the device in addition to the orientation depicted in the Figures. For example, if the device in one of the figures is turned over, elements described as being on the “lower” side of other elements would then be oriented on “upper” sides of the other elements. The exemplary term “lower,” can therefore, encompass both an orientation of “lower” and “upper,” depending of the particular orientation of the figure. Similarly, if the device in one of the figures is turned over, elements described as “below” or “beneath” other elements would then be oriented “above” the other elements. The exemplary terms “below” or “beneath” can, therefore, encompass both an orientation of above and below.

FIG. 1 is a cross-sectional view showing an array substrate 100 of a display device according to a non-limiting example embodiment of the present invention. FIG. 1 shows only a thin film transistor of a specific pixel and a storage capacitor region Cst for the convenience of description.

Referring to FIG. 1, a blocking layer 110 may be formed on a substrate 100. A first semiconductor layer 130 and a second semiconductor layer 135 may be formed using poly-silicon. The first semiconductor layer 130 and the second semiconductor layer 135 may be formed on the blocking layer 110 in a thin film transistor TFT region and a storage capacitor Cst region.

The blocking layer 110 may be formed by depositing silicon nitride (SiN_{X}) or silicon oxide (SiO₂). The blocking layer 110 serves to prevent impurities in the substrate 100 from diffusing into the first semiconductor layer 130 and the second semiconductor layer 135. Particularly, the first semiconductor layer 130 and the second semiconductor layer 135 include poly-silicon crystallized by heat generated from a laser radiation or a thermal treatment. The heat may diffuse alkali ions, such as potassium ion (K⁺) and sodium ion (Na⁺), in the substrate into the first semiconductor layer 130 and the semiconductor layer 135. The blocking layer 110 may serve to prevent the alkali ions from being diffused into the first semiconductor layer 130 and the second semiconductor layer 135. That is, the blocking layer 110 may be formed to prevent properties of the first and second semiconductor layers 130 and 135 formed using poly-silicon from being deteriorated by the alkali ions.

The semiconductor layers 130 and 135 including poly-silicon may be formed by a crystallization process. The crystallization process may changes the amorphous silicon layer into the poly-silicon layer. Examples of the crystallization process may include ELA (Excimer Laser Annealing) employing an excimer laser, SLS (Sequential Lateral Solidification) crystallization, heat treatment, or MILC (Metal Inducted Lateral Crystallization). However, non-limiting example embodiments of the present invention may not be limited thereto, and other crystallization processes may be employed. The first semiconductor layer 130 may have an active region 132 including relatively pure poly-silicon at a center area. The first semiconductor layer 130 may have a source region 132a and a drain region 132b including impurities. The source region 132a and the drain region 132b may be located at respective sides of the active region 132.

Furthermore, the second semiconductor layer 135 may be doped with impurities while doping the impurities into the source region 132a and the drain region 132b. In this case, the second semiconductor layer 135 may be conductive such that the second semiconductor layer 135 may serves as a first electrode 135 of the storage capacitor. However, non-limiting example embodiments of the present invention may not be limited thereto, and the second semiconductor layer 135 may not be doped with impurities.

Although the first and second semiconductor layers 130 and 135 may be connected in an integral structure in FIG. 1, the first and second semiconductor layers 130 and 135 may be separated from each other. In other words, a portion of the first and second semiconductor layers 130 and 135 connecting the two may be cut.

According to the present non-limiting example embodiment of the present invention, conductivity of the second semiconductor layer 135 may be changeable in various ways by the ion implant process forming the source region 132a and the drain region 132b in the first semiconductor layer 130. For example, in the ion implant process, impurities may be selectively implanted only in the source region 132a and the drain region 132b. In this case, the second semiconductor layer 135 may include un-doped poly-silicon (i.e., relatively pure poly-silicon).

In another non-limiting example embodiment of the present invention, in the ion implantation process, the impurities may be implanted in the second semiconductor layer 135 as well as the source region 132a and the drain region 132b. In this case, the second semiconductor layer 135 may include doped poly-silicon. In another non-limiting example embodiment of the present invention, the impurities may not be implanted in the connection portion of the first and second semiconductor layers 130 and 135 when the first and second semiconductor layers 130 and 135 may be integrally connected.

Furthermore, an insulating film 120 may be formed on the first and second semiconductor layers 130 and 135. A gate electrode 150 may be formed to overlap the active region 132 on the insulating film 120. A second electrode 155 may be formed to overlap the first electrode 135 on the insulating film 120. In this configuration, the insulating film 120 may be formed using an inorganic insulating material. Examples of the inorganic insulating material may include silicon nitride (SiNₓ), silicon oxide (SiO₂), etc.

The second electrode 155 may be formed on the same layer as the gate electrode 150. A first storage capacitor Cst1 may be formed by the first and second electrodes 135 and 155. The insulating film 120 may be located between the first and second electrodes 135 and 155. The insulating film 120 may serve as a dielectric. The second electrode 155 may include a transparent conductive material. Alternatively, the second electrode 155 may include an opaque conductive material. The second electrode 155 may include the same material as the gate electrode 150.

An interlayer insulating film 140 may be formed on the insulating film 120 to cover the gate electrode 150 and the second electrode 155. The insulating film 120 may have contact holes corresponding to the source and drain regions 132a and 132b, respectively. The source electrode 152 and the drain electrode 154 formed on the interlayer film 140 may be in electrical contact with the source region 132a and the drain region 132b, respectively, through the contact holes.

In the present non-limiting example embodiment, the interlayer insulating film 140 may be formed using an inorganic insulating material or an organic insulating material. Examples of the inorganic insulating material may include silicon nitride (SiNₓ), silicon oxide (SiO₂), etc. Examples of the organic insulating material may include BCB (benzo-cyclo-butene), photo acryl, etc. However, non-limiting example embodiments of the present invention may not be limited thereto, and other suitable insulating materials may be used. The first semiconductor layer 130, the gate electrode 150, and the source and drain electrodes 152 and 154 may be formed as described above and thus, a thin film transistor having a top gate structure may be implemented.

A passivation layer 160 may be formed on the source and drain electrodes 152 and 154. A contact hole may be formed through the passivation layer 160 such that the contact hole may correspond to a portion of the drain electrode 154. A pixel electrode 170 may be formed in the contact hole to contact the drain electrode 154. The passivation layer 160 may be formed using an inorganic insulating material. Examples of the inorganic insulating material may include silicon nitride (SiNₓ), silicon oxide (SiO₂), etc. Alternatively, the passivation layer 160 may include an organic insulating material. Examples of the organic insulating material may include BCB (benzo-cyclo-butene), photo acryl, etc. However, non-limiting example embodiments of the present invention may not be limited thereto, and the passivation layer 160 may be formed using other insulating materials.

However, in the thin film transistor having the top gate structure, a photo-induced leakage current may be caused by light radiated from a backlight (not shown). The photo-induced leakage current may directly enter into the active region 132 of the thin film transistor. The photo-induced leakage current may cause deterioration of the on-off characteristics of the thin film transistor, which results in bad picture quality of the display device.

Therefore, in present non-limiting example embodiment of the present invention, as shown in FIG. 1, a light block layer 112 that blocks light may be formed under the blocking layer 110. The light block layer 112 may overlap the first semiconductor layer 130. The light block layer 112 may be formed using opaque metal that may not transmit light. Thus, it may be possible to block light entering the thin film transistor from the backlight. However, non-limiting example embodiments of the present invention may not be limited thereto, and the light block layer 112 may be formed using other materials that do not transmit light. Furthermore, in the present non-limiting example embodiment, a third electrode 114 may be formed under the blocking layer 110 such that the third electrode 114 may be located on the same layer. The light block layer 112 may overlap with the first electrode 135.

In the non-limiting example embodiment shown in FIG. 1, the third electrode 114 may be formed on the same layer as the light block layer 112. The third electrode 114 may be formed in the process of forming the light block layer 112. Thus, a second storage capacitor Cst2 may include the third electrode 114, the first electrode 135, and the blocking layer 110. The blocking layer 110 located between the first electrode 135 and the third electrode 114 may serve as a dielectric. The third electrode 114 may include a transparent conductive material. However, non-limiting example embodiments of the present invention may not be limited thereto and the third electrode may include an opaque conductive material. Furthermore, the third electrode 114 may include the same material as the light block layer 112.

According to the present non-limiting example embodiment, the first and second storage capacitors Cst1 and Cst2 may be used as the storage capacitor so that it may be possible to easily achieve a required storage capacitance. Thus, it may be possible to reduce the area that the storage capacitor may occupy in the pixel region. In addition, it may be possible to implement high luminance by increasing the aperture ratio of the pixel region.

Although not shown in detail, the second electrode 155 and the third electrode 114 may be electrically connected to each other. According to another non-limiting example embodiment of the present invention, the second electrode 155 and the third electrode 114 may be used as the upper electrode and the lower electrode of the storage capacitor, respectively. The first electrode 132 may be located in a floating type configuration between the second electrode 155 and the third electrode 114.

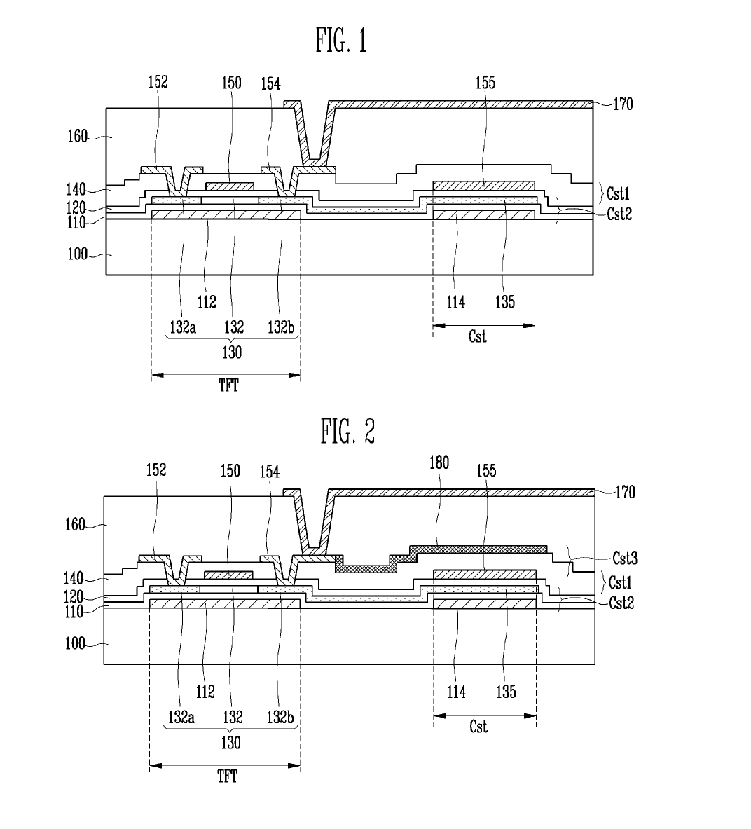

FIG. 2 is a cross-sectional view showing an array substrate of a display device according to another non-limiting example embodiment of the present invention. The non-limiting example embodiment shown in FIG. 2 may be substantially the same as the non-limiting example embodiment shown in FIG. 1 except that a fourth electrode 180 formed on the interlayer insulating layer 140 such that the fourth electrode 180 may overlap a second electrode 155. Thus, the storage capacitance may further increase.

The same components as those in the non-limiting example embodiment shown in FIG. 1 may be designated by the same reference numerals and a repeated description may be not provided. Referring to FIG. 2, a fourth electrode 180 may be formed on a portion of an interlayer insulating film 140 overlapping the second electrode 155.

However, the fourth electrode 180 may be integrally formed with the drain electrode 154 and extends to a region where a drain electrode 154 overlaps the second electrode 155. However, non-limiting example embodiments of the present invention may not be limited thereto. For example, the fourth electrode 180 may be physically connected to the drain electrode 154 as an independent conductive structure extending from the drain electrode 154 in order to be electrically connected with the drain electrode 154. The fourth electrode 180 may include a transparent conductive material. However, non-limiting example embodiments of the present invention may not be limited thereto. For example, the fourth electrode 180 may include an opaque conductive material. Furthermore, the fourth electrode 180 may include the same material as the drain electrode 154.

As described above, a third storage capacitor Cst3 may include the fourth electrode 180, the second electrode 155, and the interlayer insulating film 140. The interlayer insulating film 140 located between the second electrode 155 and the fourth electrode 180 may serve as a dielectric.

Therefore, according to the non-limiting example embodiment shown in FIG. 2, by implementing a storage capacitor in each pixel with the first to third capacitors Cst1-Cst3, it may be possible to easily achieve a required storage capacitance. Thus, it may be possible to reduce the area occupied by the storage capacitor in the pixel region and implement high luminance by increasing an aperture ratio of the pixel.

As shown in FIG. 2, the first electrode 135 may be doped or not. Though not shown in detail, the second electrode 155 and the third electrode 114 may be electrically connected. The first electrode 135 and the fourth electrode 180 may be electrically connected. However, non-limiting example embodiments of the present invention may not be limited thereto. For example, the first through fourth electrodes 135, 155, 114 and 180, respectively, may be electrically connected in other configurations. As an example, according to a non-limiting example embodiment of the present invention, the first electrode 135 and the fourth electrode 180 may be electrically connected and the second electrode 135 and the third electrode 144 may be floated between the first electrode 135 and the fourth electrode 180. According to other non-limiting example embodiments of the present invention, only the third electrode 114 may be included, or only the fourth electrode 180 may be included, or both of the third electrode 114 and the fourth electrode 180, other than the first electrode 135 and the second electrode 155, may be included.

When only the third electrode 114 may be included, the second electrode 155 may be electrically connected with the third electrode 114. When only the fourth electrode 180 may be included, the first electrode 135 may be connected with the fourth electrode 180. When the third electrode 114 and the fourth electrode 180 may be both included, the second electrode 155 may be electrically connected with the third electrode 114 and the first electrode 135 may be connected with the fourth electrode 180.

According to the non-limiting example embodiments described with reference to FIGS. 1 and 2, since each electrode implementing the storage capacitor may be formed using an opaque metal, it blocks light entering each pixel from the backlight (not shown), such that the aperture ratio can be reduced.

FIG. 3 is a cross-sectional view showing an array substrate of a display device according to a non-limiting example embodiment of the present invention. The non-limiting example embodiment shown in FIG. 3 may be substantially the same as the non-limiting example embodiment shown in FIG. 1 except that a second electrode 155′ of the storage capacitor Cst1 and a third electrode 114′ of the storage capacitor Cst2 may be formed using a transparent conductive material to improve an aperture ratio of a pixel. Therefore, the same components as those in the non-limiting example embodiment shown in FIG. 1 may be designated by the same reference numerals and repeated description may be not provided.

Referring to FIG. 3, at least one of the second electrode 155′ and the third electrode 114′ may be formed using a transparent conductive material. According to a non-limiting example embodiment of the present invention, only the second electrode 155′ may be formed using a transparent conductive material. According to another non-limiting example embodiment of the present invention, only the third electrode 114′ may be formed using a transparent conductive material. According to another non-limiting example embodiment of the present invention, both of the second electrode 155′ and the third electrode 114′ may be formed using a transparent conductive material. Examples of the transparent conductive materials can include ITO (Indium Tin Oxide), TO (Tin Oxide), IZO (Indium Zinc Oxide), and ITZO (Indium Tin Zinc Oxide). The transparent conductive materials may be used independently or mixed for use. However, non-limiting example embodiments of the present invention may not be limited thereto and the transparent conductive materials may include other suitable materials.

Furthermore, the first electrode 135 is, as described above, a semiconductor layer formed using doped poly-silicon, which may be a material that transmits light. Therefore, in the non-limiting example embodiment shown in FIG. 3, it may be possible to achieve a required storage capacitance, using the first and second storage capacitor, and also to improve the aperture ratio, because light radiated from the backlight may be transmitted through the transparent conductive materials.

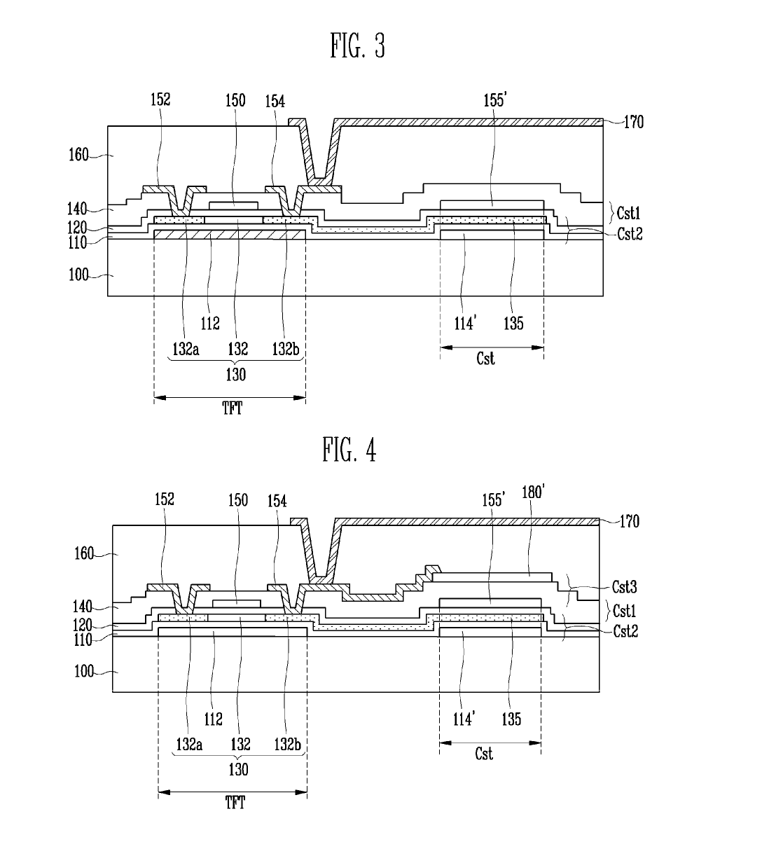

FIG. 4 is a cross-sectional view showing an array substrate of a display device according to a non-limiting example embodiment of the present invention. The non-limiting example embodiment shown in FIG. 4 may be substantially the same as the non-limiting example embodiment shown in FIG. 2, except that a second electrode 155′, a third electrode 114′, and a fourth electrode 180′ of the storage capacitor may be formed using a transparent conductive material to improve the aperture ratio of a pixel. Therefore, the same components as those in the non-limiting example embodiment shown in FIG. 2 may be designated by the same reference numerals and repeated description may be not provided.

Referring to FIG. 4, the second electrode 155′, which may be formed on the same layer as the gate electrode 150, and the third electrode 114′, which may be formed on the same layer as the light block layer 112, may be formed using a transparent conductive material. Furthermore, in the present non-limiting example embodiment, the fourth electrode 180′, may be separated from the drain electrode 154, as shown in FIG. 4, and the portion overlapping the end of the drain electrode may be formed using a transparent conductive material. In contrast, in the non-limiting example embodiment shown in FIG. 2, the fourth electrode 180 may be integrally formed with a drain electrode 154.

Examples of the transparent conductive materials include ITO (Indium Tin Oxide), TO (Tin Oxide), IZO (Indium Zinc Oxide), and ITZO (Indium Tin Zinc Oxide). The transparent conductive materials may be used independently or mixed for use. However, non-limiting example embodiments of the present invention may not be limited thereto, and the transparent conductive materials may include other suitable materials.

Furthermore, the first electrode 135 may be a semiconductor layer formed using doped poly-silicon, which may be a material that transmits light. Therefore, in the non-limiting example embodiment shown in FIG. 4, a required storage capacitance may be achievable using the first, second, and third storage capacitors Cst1-Cst3. Additionally, it may be possible to improve the aperture ratio of a pixel, because light radiated from the backlight may be transmitted through the transparent conductive materials.

However, in the non-limiting example embodiments shown in FIGS. 3 and 4, the light block layer 112 and the third electrode 114′ formed on the same layer may be formed using different materials, such that a mask process may be added to achieve this configuration.

That is, since the light block layer 112 may be formed using an opaque conductive material, such as molybdenum (Mo) and the third electrode 114′ may be formed using a transparent conductive material, such as indium tin oxide (ITO), it may be difficult to use the same mask in the process to form both the light block layer 112 and the third electrode 114′. Accordingly, the manufacturing cost or the manufacturing time may increase due to adding an additional mask process. Therefore, the following non-limiting example embodiments illustrate and describe a structure that makes it possible to simultaneously implement the light block layer 112 and the third electrode 114′ without adding the additional mask process and corresponding mask, by using a half tone mask process in forming the light block layer 112 and the third electrode 114′.

FIG. 5 may be a cross-sectional view showing an array substrate of a display device according to a non-limiting example embodiment of the present invention. The non-limiting example embodiment shown in FIG. 5 may be substantially the same as the non-limiting example embodiment shown in FIG. 3, except that a light block layer 113 may be formed in a dual layer. Therefore, the same components as those in the non-limiting example embodiment shown in FIG. 3 may be designated by the same reference numerals and repeated description may be not provided.

Referring to FIG. 5, the light block layer 113 may be composed of a first light block layer 113′, which may be formed using a transparent conductive material, and a second light block layer 113″, which may be formed using an opaque metal, both of which may be stacked upon each other. Furthermore, a third electrode 114′, which may be formed on the same layer as the light block layer 113, may be formed using the same transparent conductive material as the first light block layer 113′. This may be because a half mask process may be used to form the third electrode 114′.

In detail, the light block layer 113 may be composed of the first light block layer 113′, which may be formed using a transparent conductive material, and the second light block layer 113″, which may be formed using an opaque metal in an exposure and etching process described below. However, the third electrode 114′ may be formed using only the transparent conductive material. The light blocking layer 113 may be formed, as shown in FIG. 5, by making a thickness of a photoresistor (PR) located on the region where the third electrode 114′ may be formed smaller than a photoresistor located on the region where the light block layer 113 may be formed, and by performing a photo process after sequentially depositing the transparent material and the opaque material on the substrate. Accordingly, it may be possible to simultaneously form the light block layer 113 and the third electrode 114′ without adding the mask process.

Examples of the transparent conductive materials include ITO (Indium Tin Oxide), TO (Tin Oxide), IZO (Indium Zinc Oxide), and ITZO (Indium Tin Zinc Oxide). The transparent conductive materials may be used independently or mixed for use. However, non-limiting example embodiments of the present invention may not be limited thereto, and the transparent conductive materials may include other suitable materials.

Furthermore, examples of the opaque conductive materials include molybdenum (Mo), aluminum (Al), aluminum-neodymium (AlNd), and titanium (Ti). The opaque conductive materials may be used independently or mixed or stacked for use. However, non-limiting example embodiments of the present invention may not be limited thereto and the opaque conductive materials may include other suitable materials.

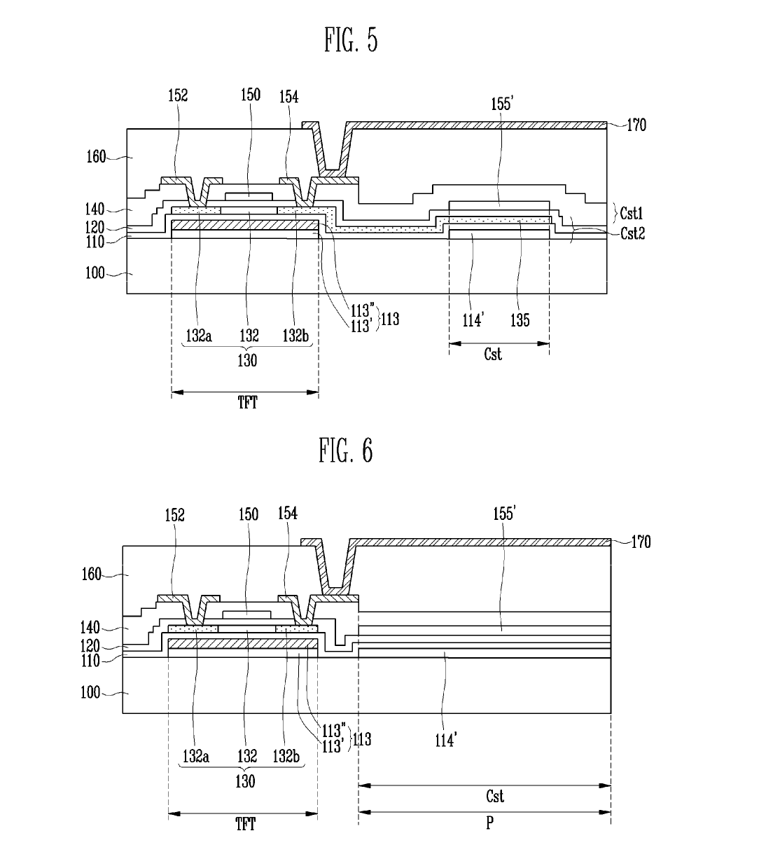

FIG. 6 may be a cross-sectional view showing an array substrate of a display device according to a non-limiting example embodiment of the present invention. The non-limiting example embodiment shown in FIG. 6 may be substantially the same as the non-limiting example embodiment shown in FIG. 5, except that the semiconductor layer 135, which may be used as a first electrode of the storage capacitor of FIG. 6, may be removed. Therefore, the same components as those in the non-limiting example embodiment shown in FIG. 5 may be designated by the same reference numerals and repeated description may be not provided.

A semiconductor layer 135, used as a first electrode of a storage capacitor Cst2 described with respect to the above non-limiting example embodiments, may be formed using doped poly-silicon and has conductivity, and transmits light. However, the semiconductor layer 135 may decrease in transmittance of light, as compared with a second electrode 114′ and a third electrode 155′, which may be formed using a transparent conductive material. Therefore, in the non-limiting example embodiment shown in FIG. 6, the semiconductor layer 135, which may be used as the first electrode of the storage capacitor in the above describe non-limiting example embodiments, may be removed to improve an aperture ratio of a pixel.

Furthermore, since the second electrode 114′ and the third electrode 155′, which may be used as electrodes of a storage capacitor, may be both formed using a transparent conductive material the aperture ration of the pixel can be increased by removing the semiconductor layer 135, which can be formed to have an area corresponding to the entire transmitting region of the pixel, such that the semiconductor layer 135 overlaps the pixel electrode 170 corresponding to a pixel transmitting region P of the pixel, as shown in FIG. 6. That is, as shown in FIG. 6, the second electrode 114′ and the third electrode 155′ may be formed to have a width corresponding to the pixel transmitting region P of the pixel, such that it may be possible to ensure sufficient electrostatic capacity, while reducing the decrease of the transmittance.

Although a few non-limiting example embodiments of the present invention have been shown and described, it would be appreciated by those skilled in the art that changes may be made in this embodiment without departing from the principles and spirit of the invention, the scope of which may be defined in the claims and their equivalents.

What is claimed is:

1. An array substrate of a display device, the array substrate comprising:
a substrate having a first region and a second region spaced apart from the first region;
a blocking layer located on the substrate;
a first electrode located on the blocking layer in the second region;
an insulating film located on the blocking layer to cover the first electrode;
a second electrode located on the insulating film to overlap the first electrode; and
a third electrode overlapping the first electrode between the substrate and the blocking layer.

2. The array substrate of claim 1, wherein the third electrode includes a transparent conductive material.

3. The array substrate of claim 1, wherein the third electrode includes an opaque conductive material.

4. The array substrate of claim 1, wherein the second electrode and the third electrode are electrically connected.

5. An array substrate of a display device, the array substrate comprising:
a substrate having a first region and a second region spaced apart from the first region;
a blocking layer located on the substrate;
a first electrode located on the blocking layer in the second region;
an insulating film located on the blocking layer to cover the first electrode;
a second electrode located on the insulating film to overlap the first electrode;
an interlayer insulating film located on the second electrode; and
a fourth electrode overlapping the second electrode on the interlayer insulating film.

6. The array substrate of claim 5, wherein the fourth electrode includes a transparent conductive material.

7. The array substrate of claim 5, wherein the fourth electrode includes an opaque conductive material.

8. The array substrate of claim 5, wherein the first electrode and the fourth electrode are electrically connected.

9. An array substrate of a display device, the array substrate comprising:
a substrate having a first region and a second region spaced apart from the first region;
a blocking layer located on the substrate;
a first electrode located on the blocking layer in the second region;
an insulating film located on the blocking layer to cover the first electrode;
a second electrode located on the insulating film to overlap the first electrode;
a third electrode overlapping the first electrode between the substrate and the blocking layer;
an interlayer insulating film located on the second electrode; and
a fourth electrode overlapping the second electrode on the interlayer insulating film.

10. The array substrate of claim 9, wherein the first electrode and the fourth electrode are electrically connected, and the second electrode and the third electrode are electrically connected.

11. An array substrate of a display device, the array substrate comprising:
a substrate having a first region and a second region spaced apart from the first region;
a blocking layer located on the substrate;
a first electrode located on the blocking layer in the second region;
an insulating film located on the blocking layer to cover the first electrode;
a second electrode located on the insulating film to overlap the first electrode; and
a transistor located in the first region, the transistor comprising:
a channel region,
a source region connected with the channel region,
a drain region, and
a gate region,
wherein the drain region and the gate region are spaced apart from the source region,
wherein the insulating film insulates the channel region, the source region, the drain region and the gate region.

12. The array substrate of claim 11, wherein the first electrode is formed on the same layer as the channel region, the source region, and the drain region.

13. An array substrate of a display device, the array substrate comprising:
a substrate having a first region and a second region spaced apart from the first region;
a blocking layer located on the substrate;
a first electrode located on the blocking layer in the second region;
an insulating film located on the blocking layer to cover the first electrode;
a second electrode located on the insulating film to overlap the first electrode;
a transistor located in the first region; and
a light block layer overlapping the transistor between the substrate and the blocking layer.

14. The array substrate of claim 13, further comprising a third electrode overlapping the first electrode between the substrate and the blocking layer.

15. The array substrate of claim 14, wherein the third electrode includes an opaque conductive material.

16. The array substrate of claim 14, wherein the third electrode includes a transparent conductive material.

17. The array substrate of claim 13, further comprising:
an interlayer insulating film covering the transistor and the second electrode; and
a fourth electrode located on the interlayer insulating film to overlap the second electrode.

18. The array substrate of claim 13, further comprising:
a third electrode overlapping the first electrode between the substrate and the blocking layer;
an interlayer insulating film covering the transistor and the second electrode; and
a fourth electrode located on the interlayer insulating film to overlap the second electrode.

19. The array substrate of claim 13, wherein the light block layer is formed using different materials stacked upon each other.

20. The array substrate of claim 19, wherein the different materials are a transparent conductive material and an opaque conductive material.

21. An array substrate of a display device, the array substrate comprising:
a substrate having a first region and a second region spaced apart from the first region;
a blocking layer located on the substrate;
a transistor located in the first region, the transistor comprising
a semiconductor layer,
a gate electrode located in a region overlapping the semiconductor layer, and
an insulating film insulating the gate electrode from the semiconductor layer;
a light block layer overlapping the transistor between the substrate and the blocking layer;
a second electrode located on the insulating film in the second region and used as the upper electrode of a storage capacitor; and
a third electrode overlapping the upper electrode of the storage capacitor, and located under the blocking layer in the second region,
wherein the third electrode is used as a lower electrode of the storage capacitor.

22. The array substrate of claim 21, wherein the second electrode and the third electrode are formed using a transparent conductive material.

23. The array substrate of claim 21, wherein the second electrode and the third electrode are formed to have a width corresponding to the entire transmitting region of each pixel.

24. The array substrate of claim 21, wherein the light block layer is formed using different materials stacked upon each other.

25. The array substrate of claim 24, wherein the different materials are formed using a transparent conductive material and an opaque conductive material.

26. A method of manufacturing an array substrate of a display device, the method comprising:
forming a light block layer in a first region on a substrate;
forming a first electrode in a second region on the substrate, the second region being spaced apart from the first region on the substrate;
forming a blocking layer on the substrate, the light block layer and the first electrode;
forming a semiconductor layer on the blocking layer in the first region, the semiconductor layer including a source region, a drain region, and an active region;
forming a second electrode on the blocking layer in the second region;
forming an insulating film on the semiconductor layer and the second electrode;
forming a gate electrode on the insulating film above the active region; and
forming a third electrode on the insulating film overlapping the first electrode.

27. The method of claim 26, further comprising:
forming an interlayer insulating layer on the insulating film, the gate electrode and the third electrode;
forming a source electrode and a drain electrode on the interlayer insulating layer, the source electrode and the drain electrode being in contact with the source region and the drain region, respectively, through via holes corresponding to the source region and the drain region in the interlayer insulating layer and the insulating film;
forming a passivation layer on the interlayer insulating layer, the source electrode and the drain electrode; and
forming a pixel electrode on the passivation layer, the pixel electrode contacting the drain electrode through a via hole formed in the passivation layer.

28. The method of claim 26, wherein the first electrode is formed using a transparent conductive material.

29. The method of claim 26, wherein the first electrode is formed using an opaque conductive material.

30. The method of claim 26, wherein the first electrode and the third electrode are electrically connected.

31. The method of claim 27, further comprising:
forming a fourth electrode between the interlayer insulating layer and the passivation layer in the second region.

32. The method of claim 31, wherein the fourth electrode contacts the drain electrode.

33. The method of claim 31, wherein the fourth electrode is formed using a transparent conductive material.

34. The method of claim 31, wherein the fourth electrode is formed using an opaque conductive material.

35. The method of claim 31, wherein the second electrode and the fourth electrode are electrically connected.

36. The method of claim 31, wherein the fourth electrode contacts the drain electrode.

37. The method of claim 26, wherein the second electrode contacts the drain region.

38. The method of claim 26, wherein the second electrode is formed on the same layer as the semiconductor layer.

39. The method of claim 26, wherein the light block layer comprises:
a transparent layer located on the substrate; and
an opaque layer located on the transparent layer and below the blocking layer.

40. A storage capacitor of a display device having an array substrate including a thin film transistor (TFT) and the storage capacitor, the storage capacitor comprising:
a first electrode located on a substrate;
a blocking layer located on the first electrode and the substrate;
a second electrode located on the blocking layer;
an insulating film located on the second electrode and the blocking layer;
a third electrode located on the insulating film and overlapping the first electrode; and
an interlayer insulting film located on the third electrode and the insulating film.

41. The storage capacitor of claim 40, wherein the first electrode is formed using a transparent conductive material.

42. The storage capacitor of claim 40, wherein the first electrode is formed using an opaque conductive material.

43. The storage capacitor of claim 40, wherein the first electrode and the third electrode are electrically connected.

44. The storage capacitor of claim 40, further comprising a fourth electrode located on the interlayer insulating film and overlapping the third electrode.

45. The storage capacitor of claim 44, wherein the fourth electrode is formed using a transparent conductive material.

46. The storage capacitor of claim 44, wherein the fourth electrode is formed using an opaque conductive material.

47. The storage capacitor of claim 44, wherein the second electrode and the fourth electrode are electrically connected.

48. The storage capacitor of claim 44, wherein the fourth electrode is connected to a drain electrode of the TFT.

49. The storage capacitor of claim 40, wherein the second electrode is connected to a drain region of the TFT.

50. The storage capacitor of claim 40, wherein the first electrode and the third electrode are formed using a transparent conductive material and both have a width of an entire transmitting region of each respective pixel of the display device.
